(19) United States
(12) Patent Application Publication
(10) Pub. No.: US 2010/0327427 A1
(43) Pub. Date: Dec. 30, 2010

(54) Semiconductor device and method for manufacturing the same

(75) Inventors: Takehiro Kimura, Kanagawa (JP); Yoichiro Kurita, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/662,805

(22) Filed: May 4, 2010

(30) Foreign Application Priority Data
Jun. 29, 2009 (JP) 2009-153374

(51) Int. Cl. H01L 23/31; H01L 21/56; H01L 21/60

(52) U.S. Cl. 257/692; 438/124; 257/E21.503; 257/E21.504; 257/E21.506; 257/E23.124

(57) ABSTRACT

A semiconductor device includes a wiring layer, a semiconductor chip which is arranged on the wiring layer with a gap there between, the semiconductor chip being electrically connected to the wiring layer through a connecting portion, a first sealing member which is filled in a space between the wiring layer and the semiconductor chip, and a second sealing member which coats the semiconductor chip. The first sealing member and the second sealing member include same organic resin, the organic resin including inorganic filler. The second sealing member has larger content of inorganic filler than the first sealing member.

### INCORPORATION BY REFERENCE

This application is based upon and claims the benefit of priority from Japanese patent application No. 2009-153374, filed on Jun. 29, 2009, the disclosure of which is incorporated herein in its entirety by reference.

### BACKGROUND

1. Field of the Invention

The present invention relates a semiconductor device and a method for manufacturing the same.

2. Description of Related Art

In a semiconductor device of flip-chip type, a substrate is connected to a semiconductor chip through a bump. In such a semiconductor device, a sealing member is filled between the substrate and the semiconductor chip by using so-called “capillary flow technique”. The sealing member protects a connection portion between the substrate and the semiconductor chip. At this time, the sealing member includes inorganic filler to fully protect the connection portion between the substrate and the semiconductor chip. However, if the inorganic filler is included too much, viscosity of the sealing member becomes increased, and then it becomes difficult to fill the space between the substrate and the semiconductor chip with the sealing member.

In the technique of Japanese Unexamined Patent Application Publication No. 2008-270257 (Ishikawa), a member made of a solid-state material which has lower thermal expansion coefficient than that of the sealing member is put in the space between the substrate and the semiconductor chip, and the sealing member is filled in the other portion of the member. By putting the member in the space between the substrate and the semiconductor chip, the inorganic filler which is included in the sealing member can be decreased, and filling efficiency of the sealing member can be increased.

### SUMMARY

However, in the technique of Ishikawa, since it is necessary to put the member in the space between the substrate and the semiconductor chip, manufacturing of semiconductor devices becomes complicated and the manufacturing cost of semiconductor devices becomes increased.

According to an embodiment of the present invention, there is provided a semiconductor device including a wiring layer, a semiconductor chip which is arranged on the wiring layer with a gap there between, the semiconductor chip being electrically connected to the wiring layer through a connecting portion, a first sealing member which is filled in a space between the wiring layer and the semiconductor chip, and a second sealing member which coats the semiconductor chip. The first sealing member and the second sealing member include organic resin and inorganic filler, the organic resin of the first sealing member and the organic resin of the second sealing member being the same, and the second sealing member has larger content of inorganic filler than the first sealing member.

Thus, by forming a layer (a first sealing member 61) which has low content rate of the inorganic filler and low modulus of elasticity under the semiconductor chip 3, the effect of stress relaxation of a board implementation will be achieved. Therefore, since it is not necessary to put a member which has low thermal expansion coefficient in the space between the substrate and the semiconductor chip, the manufacturing of semiconductor devices becomes easy and manufacturing cost of semiconductor devices can be reduced.

According to another embodiment of the present invention, there is provided a semiconductor device including a wiring layer, a wiring layer, a semiconductor chip which is arranged on the wiring layer with a gap there between, the semiconductor chip being electrically connected to the wiring layer through a connecting portion, a first sealing member which is filled in a space between the wiring layer and the semiconductor chip, and a second sealing member which coats the semiconductor chip. The first sealing member and the second sealing member include organic resin and inorganic filler, the organic resin of the first sealing member and the organic resin of the second sealing member being the same. The inorganic filler includes a first inorganic filler and a second inorganic filler, a diameter of the first inorganic filler being such that the first inorganic filler can pass through the space between the wiring layer and the semiconductor chip, a diameter of the second inorganic filler being larger than that of the first inorganic filler. The organic resin of the first sealing member includes a part of the first inorganic filler. The organic resin of the second sealing member includes the rest of the first inorganic filler and the second inorganic filler.

Consequently, since a layer (a first sealing member 61) which has low content rate of the inorganic filler and low modulus of elasticity is formed under the semiconductor chip 3, the effect of stress relaxation of a board implementation will be achieved. Thus, since it is not necessary to put a member which has low thermal expansion coefficient in the space between the substrate and the semiconductor chip, the manufacturing of semiconductor devices becomes easy and manufacturing cost of semiconductor devices can be reduced.

According to yet another embodiment of the present invention, there is provided a manufacturing method for semiconductor device including electrically connecting a wiring layer and a semiconductor chip through a connection portion with a gap there between, and mold sealing the semiconductor chip with an organic resin including inorganic filler, the inorganic filler having different diameters. The mold sealing includes coating the semiconductor chip with the organic resin, the organic resin having inorganic filler whose diameter is larger than that of inorganic filler included in the organic resin filled in a space between the wiring layer and the semiconductor chip. A content of inorganic filler included in the organic resin coating the semiconductor chip is larger than a content of inorganic filler included in the organic resin filled in the space between the wiring layer and the semiconductor chip.

Therefore, since a layer (a first sealing member 61) which has low content rate of the inorganic filler and low modulus of elasticity is formed under the semiconductor chip 3, the effect of stress relaxation of a board implementation will be achieved.

The present invention can provide a semiconductor device and a method for manufacturing the same which can be easily manufactured and reduce the manufacturing cost.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a cross-section view showing a semiconductor device of an exemplary embodiment of the present invention;

FIG. 2 is an enlarged section view of FIG. 1;

FIG. 3 is a process drawing showing a method for manufacturing the semiconductor device of the present invention;

FIG. 4 is a process drawing showing a method for manufacturing the semiconductor device of the present invention;

FIG. 5 is a process drawing showing a method for manufacturing the semiconductor device of the present invention;

FIG. 6 is a process drawing showing a method for manufacturing the semiconductor device of the present invention;

FIG. 7 is a process drawing showing a method for manufacturing the semiconductor device of the present invention; and

FIG. 8 is a process drawing showing a method for manufacturing the semiconductor device of the present invention.

### DETAILED DESCRIPTION OF THE EXEMPLARY EMBODIMENTS

Hereinafter, a specific embodiment to which the present invention is applied will be described in detail with reference to the drawings. Note that, the exemplary embodiment is simplified for the sake of convenience. The technical scope of the present invention should not be limitedly interpreted based on the description of figures, because all figures are simplified. Figures are entirely used for explanation of technical matters and each element shown in figures does not reflect accurate size of each element. The same components are denoted by the same reference symbols throughout the drawings, and a redundant description thereof is omitted as appropriate for clarification of the explanation.

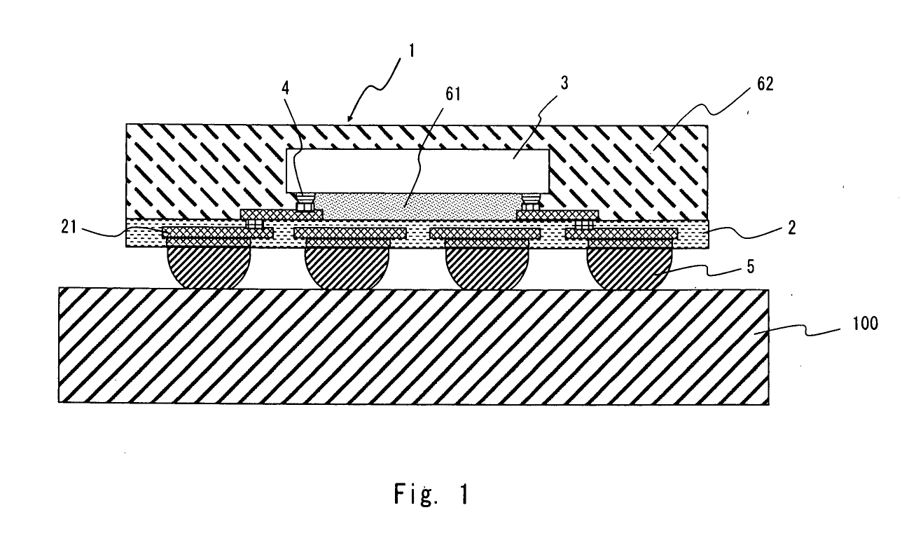

As shown in FIG. 1, in a semiconductor device 1, a wiring layer (substrate) 2 is connected to a semiconductor chip 3 with flip-chip bonding through a bump (connecting portion) 4. The wiring layer 2 and the semiconductor chip 3 are arranged with a space interposed there between. That is, the wiring layer 2 includes a wire 21. On an upper surface side of the wiring layer 2, the semiconductor chip 3 is mounted. On a bottom surface side of the semiconductor chip 3, a plurality of bumps 4 are formed along circumference with intervals. The bump 4 is electrically connected to the wire 21 of the wiring layer 2. In a bottom surface side of the wiring layer 2, a bump 5 is electrically connected to the wire 21 of the wiring layer 2. The bump 5 is electrically connected to a mounting board 100.

The semiconductor device 1 includes a first sealing member 61 and a second sealing member 62. The first sealing member 61 is filled in a space between the wiring layer 2 and the semiconductor chip 3. The second sealing member 62 coats the semiconductor chip 3. The second sealing member 62 has a larger content of inorganic filler than the first sealing member 61. That is, the first sealing member 61 which has a smaller content of the inorganic filler is filled in the space between the wiring layer 2 and the semiconductor chip 3. An upper surface and a side surface of the semiconductor chip 3 which require hardness in order to protect the semiconductor chip 3 are coated by the second sealing member 62 which has larger content of inorganic filler. So even if a special member is not prepared, a connection portion between the wiring layer 2 and the semiconductor chip 3 can be protected and the upper surface and side surface of the semiconductor chip 3 can also be protected. Because of this, the semiconductor device 1 can be easily manufactured, and this can contribute reducing of the cost of manufacturing. Further, the space between the wiring layer 2 and the semiconductor chip 3 is filled with the first sealing member 61 which has smaller content of inorganic filler. Therefore, when the mounting board 100 in which the semiconductor device 1 is mounted is thermally expanded, thermal expansion of the semiconductor chip 3 is not inhabited. In summary, the effect of stress relaxation of the board implementation can be achieved, since a layer (a first sealing member 61) which has a smaller content of the inorganic filler and low modulus of elasticity is formed under the semiconductor chip 3. Thus, thermal expansion of the mounting board 100 can be absorbed by the semiconductor chip 3, and damage of the semiconductor chip 3 can be decreased.

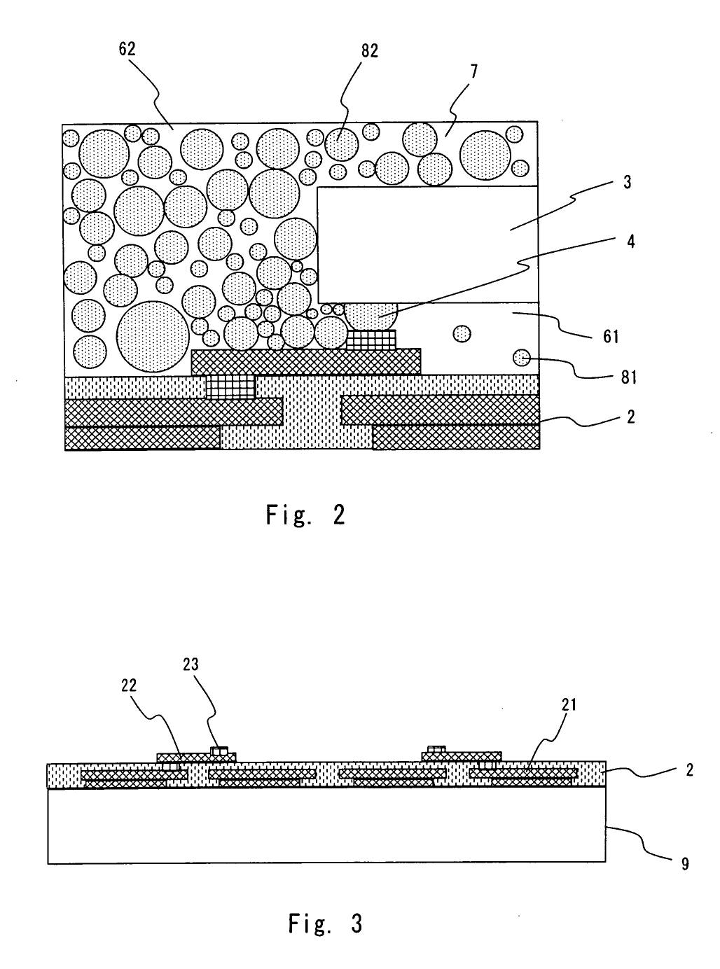

As shown in FIG. 2, the first sealing member 61 includes an organic resin 7 and a first inorganic filler 81. The organic resin 7 may be epoxy resin, polyimide resin, and silicone resin and so on. The first inorganic filler 81 may be silica, alumina and so on. The first inorganic filler 81 has such a diameter that it can pass through the space between the wiring layer 2 and the semiconductor chip 3, more preferably, through the gap surrounded by the neighboring bump 4, the wiring layer 2 and the semiconductor chip 3. That is, there is no need for the first inorganic filler 81 to be spherical shape, but its diameter (cross-section shape) is the size (shape) so that it can pass through the space or the gap. Hence, the first inorganic filler 81 can pass through the space or the gap. Incidentally, the diameter of the first inorganic filler 81 is desirably from 0.1 μm to 20 μm. However, the diameter of the first inorganic filler 81 can be changed depending on the interval of neighboring bumps 4 and so on. Note that, the first sealing member 61 may include the first inorganic filler 81 whose diameter is smaller than 0.1 μm. Here, the diameter of the first inorganic filler 81 means a diameter if the shape of the first inorganic filler 81 is spherical shape, and means a minor axis if the shape of the first inorganic filler 81 is oval sphere. In short, the first inorganic filler 81 may have any cross-sectional shape as long as it can pass through the space or the gap.

The second sealing member 62 includes the organic resin 7 and the second inorganic filler 82. The organic resin 7 is common to the first sealing member 61. The second inorganic filler 82 is made of the same material as the first inorganic filler 81. That is, the first inorganic filler 81 and the second inorganic filler 82 consist of the same composition. However, the first inorganic filler 81 may consist of a different composition from the second inorganic filler 82. A diameter of the second inorganic filler 82 is larger than that of the first inorganic filler 81. That is, it is not necessary for the second inorganic filler 82 to be spherical shape, but a diameter or cross-sectional shape is larger than the width or height of the gap.

Hence, if the second inorganic filler 82 tries to enter the space between the wiring layer 2 and the semiconductor chip 3 through the gap, the second inorganic filler 82 cannot pass through it. Incidentally, the diameter of the second inorganic filler 82 is desirably from 20 μm to 120 μm. However, the diameter of the second inorganic filler 82 can also be changed depending on the interval of neighboring bumps 4 and so on. Here, the diameter of the second inorganic filler 82 means a diameter if the shape of the second inorganic filler 82 is spherical shape, and the diameter means a minor axis if the shape of the second inorganic filler 82 is oval sphere. In short, the second inorganic filler 82 may have any cross-sectional shape as long as it cannot pass through the gap.

The first sealing member 61 and second sealing member 62 are preferably injection molded. That is the first inorganic filler 81 and the second inorganic filler 82 are included in the organic resin 7, and the organic resin 7 is injected. By this, a part of the first inorganic filler 81 is filled in the space between the wiring layer 2 and the semiconductor chip 3 together with the organic resin 7 through the gap, and thus the first sealing member 61 is formed by the first inorganic filler 81 and the organic resin 7.

Then, the organic resin 7 which includes the rest of the first inorganic filler 81 which does not enter from the gap due to a condition of the injection of the organic resin 7 and an incursion condition into the gap and the second inorganic filler 82 which gets stuck between the bumps 4, the wiring layer 2 and the semiconductor chip 3 coats the upper surface and the side surface of the semiconductor chip 3, and the first inorganic filler 81, the second inorganic filler 82 and the organic resin 7 form the second sealing member 62. Consequently, the second sealing member 62 includes larger amount of inorganic filler than the first sealing member 61. Note that, in the present exemplary embodiment, the first sealing member 61 and the second sealing member 62 are formed by the injection molding. However, a common molding technique such as vacuum compression molding can be used.

In the semiconductor device 1 stated above, the space between the wiring layer 2 and the semiconductor chip 3 is easily filled with the first sealing member 61 by only injection molding the organic resin 7 which includes the first inorganic filler 81 and the second inorganic filler 82 which have different diameters, and the upper surface and side surfaces of the semiconductor chip 3 are coated with the second sealing member 62. Therefore, the semiconductor device 1 can be manufactured easily, and this contributes reducing of the manufacturing cost. That is, like the present exemplary embodiment, when the upper surface and side surfaces are coated with a sealing member, the sealing member is injection molded only once after filling the sealing member into the space between the wiring layer and the semiconductor chip with so-called capillary flow technique. That is, it is not necessary to coat the upper surface and side surface of the semiconductor chip 3 with a common molding technique, so the great effect can be attained.

Incidentally, a content amount of the inorganic filler of the first sealing member 61 is preferably equal to or lower than 30% by weight and a content of the inorganic filler of the second sealing member 62 is preferably equal to or more than 70% by weight. A total of the content amount of the inorganic filler of the first sealing member 61 and the content of the inorganic filler of the second sealing member 62 are 100% by weight.

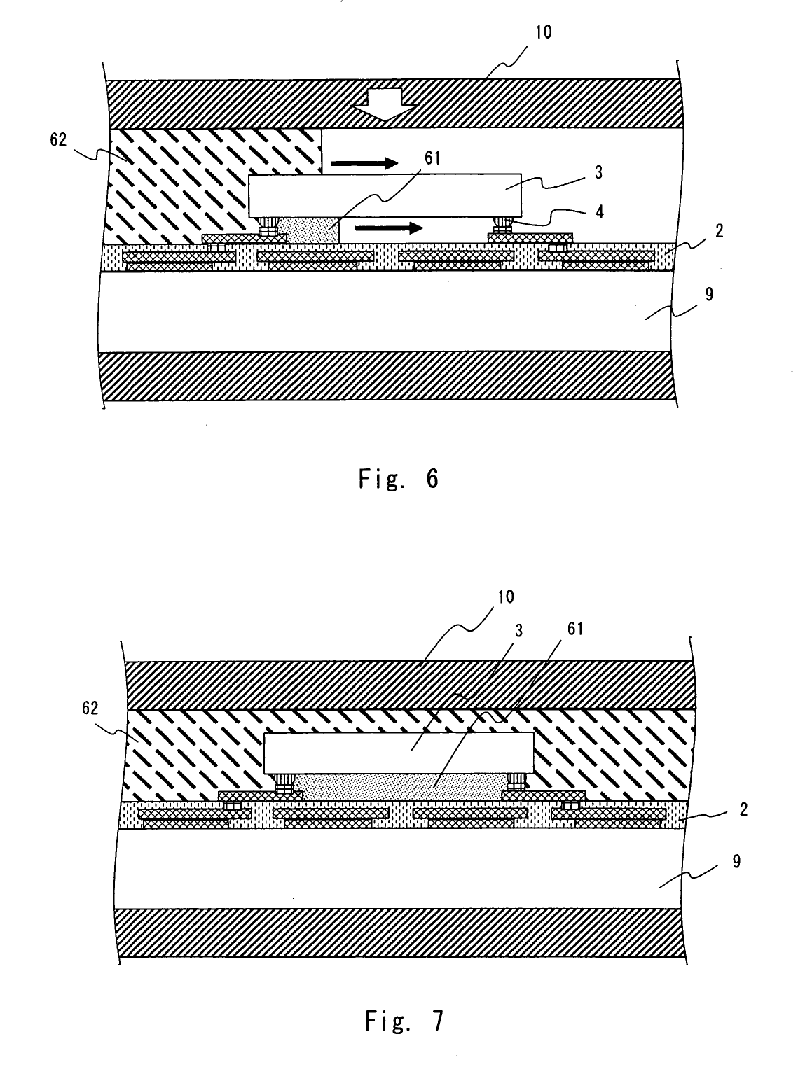

This semiconductor device 1 is manufactured as shown in FIGS. 3 to 8. Firstly, as shown in FIG. 3, the wiring layer 2 is formed. Specifically, the wire 21 is formed in a polyimide film formed on a support member 9 by means of photolithographic technique, and then the flexible wiring layer 2 is formed. Further, a wire 22 is formed on an upper surface of the wiring layer 2, and an electrode 23 is formed on the wire 22.

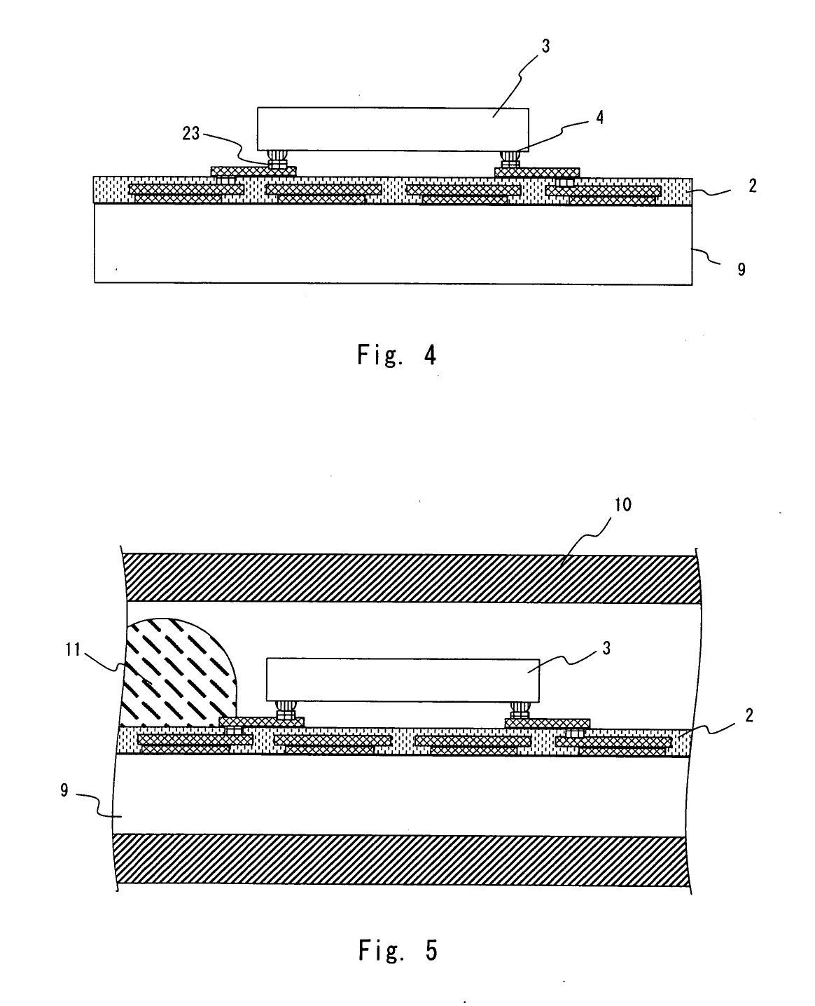

Next, as shown in FIG. 4, the semiconductor chip 3 is mounted on the upper surface side of the wiring layer 2, and the electrode 23 of the wiring layer 2 is electrically connected to the bump 4 formed on a lower side of the semiconductor chip 3. At this time, the bumps 4 are arranged along circumference of the lower surface of the semiconductor chip 3.

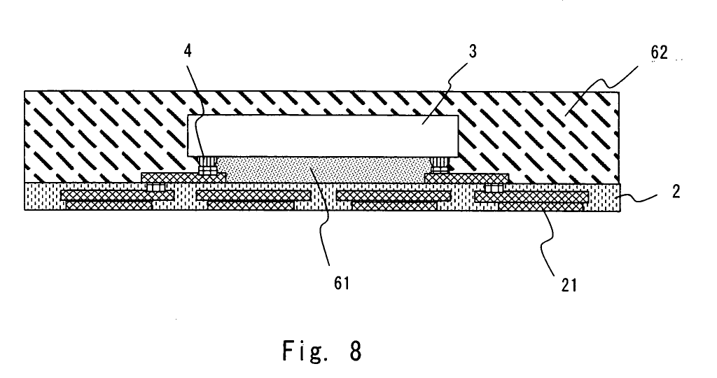

Next, as shown in FIG. 5, the wiring layer 2 which is electrically connected to the semiconductor chip 3 is put in a mold tool 10 in order to protect the connection portion of the wiring layer 2 and the semiconductor chip 3, and upper surface and side surface of the semiconductor chip 3 by sealing member. Then the sealing member 11 is injected into the vacuum mold tool 10. As above-mentioned, the sealing member 11 includes the first inorganic filler 81 and the second inorganic filler 82 in an organic resin. Therefore, as shown in FIGS. 2, 6 and 7, a part of the first inorganic filler 81 is filled in the space between the wiring layer 2 and the semiconductor chip 3 through the gap between adjacent bumps 4, the wiring layer 2, and the semiconductor chip 3 together with the organic resin 7, and the first inorganic filler 81 and the organic resin 7 form the first sealing member 61. Further, the organic resin 7 coats upper surface and side surface of the semiconductor chip 3, and the first inorganic filler 81, second inorganic filler 82 and organic resin 7 form the second sealing member 62. At this time, the organic resin 7 includes the rest of the first inorganic filler 81 which was not injected into the gap because of the condition of the injection of the organic resin 7 or an incursion condition into the gap, and the second inorganic filler 82 which gets stuck between the bump 4, the wiring layer 2 and the semiconductor chip 3. In consequence, the second sealing member 62 has larger amount of the inorganic filler than the first sealing member 61. Next, as shown in FIG. 8, the wiring layer 2 and the semiconductor chip 3 which are coated with the sealing member are removed from the mold tool 10 and the support member 9 is detached. Finally, the wire 21 which is exposed from lower surface of the wiring layer 2 is connected to the bump 5, and then the semiconductor device 1 shown in FIG. 1 is manufactured.

In the manufacturing method of the semiconductor device 1, the organic resin 7 which includes the first inorganic filler 81 and the second inorganic filler 82 having different diameters injection molded. By only this, the space between the wiring layer 2 and the semiconductor chip 3, is filled with the first sealing member 61 and the upper surface and side surface of the semiconductor chip 3 can be coated with the second sealing member 62.

Therefore, the semiconductor device 1 is manufactured easier and the manufacturing cost can be reduced. That is, when the upper surface and side surface of the semiconductor chip 3 is coated with a sealing member, it is unnecessary to coat the upper surface and side surface of the semiconductor chip 3 with a common molding technique after filling the space between the wiring layer and the semiconductor chip with a sealing member by so-called capillary flow technique. Thus, the sealing member is injection molded only once, therefore great effect can be attained.

It is apparent that the present invention is not limited to the above exemplary embodiment but may be modified and changed without departing from the scope and spirit of the invention. For example, although a flexible wiring layer is used in the above exemplary embodiment, it is not limited to this. For example, a wiring layer which is used for a typical semiconductor device can be used. At this time, in a manufacturing process, the support member 9 can be omitted. Further, in the above exemplary embodiment, the space between the wiring layer 2 and the semiconductor chip 3 is filled with the first sealing member 61 including the first inorganic filler 81. However, the first sealing member 61 does not need to include the first inorganic filler 81. Furthermore, the wire 21 exposed from lower surface of the wiring layer 2 is connected to the bump 5 in the final process, but a sealing process may be performed after connecting the wire 21 into the bump 5. Further, although the bump 4 provided in lower surface of the semiconductor chip 3 is connected to the wire 21 of the wiring layer 2 in the above exemplary embodiment, the bump 4 may be provided on the wire 21 of the wiring layer 2 preliminarily, then the bump 4 can be connected to the semiconductor chip 3.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

1. A semiconductor device comprising:
a wiring layer;
a semiconductor chip which is arranged on the wiring layer with a gap there between, the semiconductor chip being electrically connected to the wiring layer through a connecting portion;
a first sealing member which is filled in a space between the wiring layer and the semiconductor chip; and
a second sealing member which coats the semiconductor chip,
wherein the first sealing member and the second sealing member include organic resin and inorganic filler, the organic resin of the first sealing member and the organic resin of the second sealing member being the same, and the second sealing member has a larger content of inorganic filler than the first sealing member.

2. The semiconductor device according to claim 1, wherein the inorganic filler of the first sealing member and the inorganic filler of the second sealing member have the same composition.

3. The semiconductor device according to claim 1, wherein the inorganic filler of the first sealing member and the inorganic filler of the second sealing member have different compositions.

4. The semiconductor device according to claim 1,
wherein the inorganic filler includes a first inorganic filler and a second inorganic filler, a diameter of the first inorganic filler being such that the first inorganic filler can pass through the space between the wiring layer and the semiconductor chip, a diameter of the second inorganic filler being larger than that of the first inorganic filler,
wherein the organic resin of the first sealing member includes a part of the first inorganic filler, and
wherein the organic resin of the second sealing member includes the rest of the first inorganic filler and the second inorganic filler.

5. The semiconductor device according to claim 4, wherein the diameter of the first inorganic filler is such that the first inorganic filler can pass through a gap, and the gap is surrounded by adjacent connecting portion, the wiring layer and the semiconductor chip.

6. The semiconductor device according to claim 4, wherein the diameter of the first inorganic filler is equal to or more than 0.1 μm, and is equal to or less than 20 μm.

7. The semiconductor device according to claim 4, wherein the diameter of the second inorganic filler is equal to or more than 20 μm, and is equal to or less than 120 μm.

8. The semiconductor device according to claim 1, wherein a content of inorganic filler of the first sealing member is equal to or less than 30% by weight, and a content of inorganic filler of the second sealing member is equal to or more than 70% by weight.

9. The semiconductor device according to claim 1, wherein the connecting portion is arranged along a circumference of the semiconductor chip.

10. A semiconductor device comprising:
a wiring layer;
a semiconductor chip which is arranged on the wiring layer with a gap there between, the semiconductor chip being electrically connected to the wiring layer through a connecting portion;
a first sealing member which is filled in a space between the wiring layer and the semiconductor chip; and
a second sealing member which coats the semiconductor chip,
wherein the first sealing member and the second sealing member include organic resin and inorganic filler, the organic resin of the first sealing member and the organic resin of the second sealing member being the same,
wherein the inorganic filler includes a first inorganic filler and a second inorganic filler, a diameter of the first inorganic filler being such that the first inorganic filler can pass through the space between the wiring layer and the semiconductor chip, a diameter of the second inorganic filler being larger than that of the first inorganic filler,
wherein the organic resin of the first sealing member includes a part of the first inorganic filler, and
wherein the organic resin of the second sealing member includes the rest of the first inorganic filler and the second inorganic filler.

11. A manufacturing method for semiconductor device comprising:
electrically connecting a wiring layer and a semiconductor chip through a connection portion with a gap there between; and
mold sealing the semiconductor chip with a organic resin including inorganic filler, the inorganic filler having different diameters,
wherein the mold sealing includes coating the semiconductor chip with the organic resin, the organic resin having an inorganic filler whose diameter is larger than that of an inorganic filler included in the organic resin filled in a space between the wiring layer and the semiconductor chip, and
wherein a content of inorganic filler included in the organic resin coating the semiconductor chip is larger than a content of inorganic filler included in the organic resin filled in the space between the wiring layer and the semiconductor chip.

12. The manufacturing method for semiconductor device according to claim 11,
wherein the mold sealing comprises mold sealing the semiconductor chip with the organic resin including a first inorganic filler and a second inorganic filler, a diameter of the first inorganic filler being such that the first inorganic filler can pass through the space between the wiring layer and the semiconductor chip, a diameter of the second inorganic filler being larger than that of the first inorganic filler, and
wherein the organic resin including a part of the first inorganic filler is filled into the space between the wiring layer and the semiconductor chip, and the organic resin including the rest of the first inorganic filler and the second inorganic filler coat the semiconductor chip.

13. The manufacturing method for semiconductor device according to claim 12,
wherein the diameter of the first inorganic filler is such that the first inorganic filler can pass through a gap, and the gap is surrounded by adjacent connection portion, the wiring layer and the semiconductor chip,
wherein the space between the wiring layer and the semiconductor chip is filled up with the organic resin including a part of the first inorganic filler by passing a part of the first inorganic filler and the organic resin through the gap.

14. The manufacturing method for semiconductor device according to claim 12, wherein the inorganic filler of the first sealing member and the inorganic filler of the second sealing member have the same composition.

15. The manufacturing method for semiconductor device according to claim 12, wherein the inorganic filler of the first sealing member and the inorganic filler of the second sealing member have different compositions.

16. The manufacturing method for semiconductor device according to claim 12, wherein the diameter of the first inorganic filler is equal to or more than 0.1 μm, and is equal to or less than 20 μm.

17. The manufacturing method for semiconductor device according to claim 12, wherein the diameter of the second inorganic filler is equal to or more than 20 μm, and is equal to or less than 120 μm.

18. The manufacturing method for semiconductor device according to claim 11, wherein a content of inorganic filler of the first sealing member is equal to or less than 30% by weight, and a content of inorganic filler of the second sealing member is equal to or more than 70% by weight.

19. The manufacturing method for semiconductor device according to claim 11, further comprising:
forming a wiring layer on a support member: and
removing the support member,
wherein after forming the wiring layer on a support member, the wiring layer and a semiconductor chip are electrically connected through a connection portion with a gap there between, and after mold sealing the semiconductor chip with an organic resin including inorganic filler having different diameters, the support member is removed.
